(19) United States
(12) Patent Application Publication
(10) Pub. No.: US 2012/0156623 A1
(43) Pub. Date: Jun. 21, 2012

(54) SEMICONDUCTOR DEVICE MANUFACTURING METHOD, EXPOSURE METHOD FOR EXPOSURE APPARATUS, EXPOSURE APPARATUS, AND LIGHT SOURCE FOR EXPOSURE APPARATUS

(75) Inventor: Seiichiro SHIRAI, Kanagawa (JP)

(73) Assignee: RENESAS ELECTRONICS CORPORATION, Kanagawa (JP)

(21) Appl. No.: 13/313,069

(22) Filed: Dec. 7, 2011

(30) Foreign Application Priority Data
Dec. 17, 2010 (JP) 2010-281404

(51) Int. Cl. G03F 7/20; G21K 5/00

(52) U.S. Cl. 430/319; 250/492.2

(57) ABSTRACT

A semiconductor device manufacturing method which improves exposure characteristics. The method includes the step of making preparations for use of an exposure apparatus. The apparatus includes a light emitting unit with a first electrode and a second electrode for generating EUV light, a heating light source for heating the first electrode and the second electrode, and an exposure unit for projecting the EUV light on a substrate through a mask. The method also includes the following steps: heating the first electrode and the second electrode by the heating light source; after the heating step, applying a voltage between the first electrode and the second electrode and generating EUV light by plasma excitation of predetermined atoms; and leading the EUV light into the exposure unit and making an exposure on a photosensitive film formed over the substrate inside the exposure unit.

### CROSS-REFERENCE TO RELATED APPLICATIONS

The disclosure of Japanese Patent Application No. 2010-281404 filed on Dec. 17, 2010 including the specification, drawings and abstract is incorporated herein by reference in its entirety.

### BACKGROUND

The present invention relates to a semiconductor device manufacturing method, an exposure method for an exposure apparatus, an exposure apparatus, and a light source for an exposure apparatus, and more particularly to semiconductor device manufacturing technology including an exposure process with extreme ultraviolet (EUV) light.

In semiconductor device manufacturing processes, lithography (exposure and development) is used as a technique to make a pattern over the main surface of a semiconductor substrate (wafer). Generally a projection exposure apparatus is used for this lithographic technique, in which exposure light passing through a mask (original) loaded on the projection exposure apparatus is projected on the resist coated over the main surface of the wafer to transfer the mask pattern made on the photo-mask to the resist.

In recent years, demand for higher integration and higher speed of semiconductor devices has been growing and in order to respond to this demand, miniaturization of patterns has been pursued. In order to meet the need for the miniaturization of patterns, efforts have been continued to increase the resolution of projection images by the use of short wavelengths for exposure. For example, lithographic technology which uses EUV (Extreme Ultra-Violet) light with a wavelength (13.5 nm), one digit or more shorter than existing KrF (248 nm) or ArF (193 nm) ultraviolet laser light, is considered as one approach in this direction.

For example, Japanese Unexamined Patent Publication No. 2005-243771 discloses a technique that a pattern image of a mask (111) is projected on a photosensitive substrate (112) by exposure light (108) from a light source (101) through a plurality of optical elements and in the exposure process, at least two of the optical elements are irradiated with preheating light (the numbers in the parentheses are reference numbers used in the patent document).

### SUMMARY

The present inventors have been engaged in research and development of exposure technology using EUV light. In the course of doing research on exposure technology using EUV light, the inventors found a drop in the output of EUV light which will be described in detail later.

An object of the present invention is to provide a semiconductor device manufacturing method which improves exposure characteristics and improves the characteristics of semiconductor devices.

Another object of the present invention is to provide a semiconductor device manufacturing method which improves exposure characteristics and improves throughput.

The above and further objects and novel features of the invention will more fully appear from the following detailed description in this specification and the accompanying drawings.

The main aspects of the present invention which will be disclosed herein are briefly outlined below.

According to a first main aspect of the present invention, there is provided a semiconductor device manufacturing method which includes the step of (a) making preparations for use of an exposure apparatus. The apparatus includes: (a1) a light emitting unit with a first electrode and a second electrode for generating EUV light; (a2) a heating unit for heating the first electrode and the second electrode; and (a3) an exposure unit for projecting the EUV light on a substrate through a mask. The method further includes the step of (b) heating the first electrode and the second electrode by the heating unit. Further, after the above heating step (b), the method includes the following steps: (c) applying a voltage between the first electrode and the second electrode and generating EUV light by plasma excitation of predetermined atoms and (d) leading the EUV light into the exposure unit and making an exposure on a photosensitive film formed over the substrate inside the exposure unit.

According to a second main aspect of the invention, there is provided an exposure apparatus which includes (a1) a light emitting unit with a first electrode and a second electrode which generates EUV light by plasma excitation of predetermined atoms between the first electrode and the second electrode by applying a voltage between the first electrode and the second electrode. Further, the apparatus includes (a2) a heating unit for heating the first electrode and the second electrode and (a3) an exposure unit for projecting the EUV light on a substrate through a mask.

According to a third main aspect of the invention, there is provided an exposure method which uses an exposure apparatus described next. The exposure apparatus includes (a1) a light emitting unit with a first electrode and a second electrode for generating EUV light by plasma excitation of predetermined atoms between the first electrode and the second electrode by applying a voltage between the first electrode and the second electrode and (a2) a heating unit for heating the first electrode and the second electrode. The apparatus further includes (a3) an exposure unit for projecting the EUV light on a substrate through a mask. Using the exposure apparatus, the first electrode and the second electrode are heated by the heating unit before leading the EUV light into the exposure unit and making an exposure on a photosensitive film formed over the substrate inside the exposure unit.

According to a fourth main aspect of the invention, there is provided a light source for an exposure apparatus which includes (a1) a light emitting unit with a first electrode and a second electrode for generating EUV light by plasma excitation of predetermined atoms between the first electrode and the second electrode by applying a voltage between the first electrode and the second electrode and (a2) a heating unit for heating the first electrode and the second electrode.

According to the semiconductor device manufacturing method in a preferred embodiment of the invention described below, the characteristics of semiconductor devices can be improved.

According to the semiconductor device manufacturing method in a preferred embodiment of the invention described below, the productivity in the manufacture of semiconductor devices can be increased.

According to the exposure apparatus in a preferred embodiment of the invention described below, exposure characteristics can be improved.

According to the exposure method in a preferred embodiment of the invention described below, exposure characteristics can be improved.

According to the light source for an exposure apparatus in a preferred embodiment of the invention described below, exposure characteristics can be improved.

### BRIEF DESCRIPTION OF THE DRAWINGS

FIG. 1 is a block diagram showing the structure of an exposure apparatus used in a semiconductor device manufacturing method according to a first embodiment;

FIG. 2 is a schematic sectional view showing a light emitting unit, a light collecting unit and their vicinities according to the first embodiment;

FIG. 3 shows the negative electrode and positive electrode of the light emitting unit shown in FIG. 2 in which the negative electrode is shown on the left in a perspective view and the positive electrode is shown on the right in a perspective view;

FIG. 4 is a sectional view showing an example of a collector (light collecting optics);

FIG. 5 is a perspective view showing the collector (light collecting optics);

FIG. 6 is a sectional view of an essential part of a substrate illustrating a semiconductor device manufacturing step according to the first embodiment;

FIG. 7 is a sectional view of the essential part of the substrate illustrating a semiconductor device manufacturing step next to the step shown in FIG. 6 according to the first embodiment;

FIG. 8 is a sectional view of the essential part of the substrate illustrating a semiconductor device manufacturing step next to the step shown in FIG. 7 according to the first embodiment;

FIG. 9 is a sectional view of the essential part of the substrate illustrating a semiconductor device manufacturing step next to the step shown in FIG. 8 according to the first embodiment;

FIG. 10 is a sectional view of the essential part of the substrate illustrating a semiconductor device manufacturing step next to the step shown in FIG. 9 according to the first embodiment;

FIG. 11 is a graph showing the relation between wafer processing time (number of wafers) and output for a comparative example which does not involve a heating step for the electrodes, etc.;

FIG. 12 is a graph showing the relation between non-exposure time and output difference;

FIG. 13 is a schematic sectional view showing a light emitting unit, a light collecting unit and their vicinities in an exposure apparatus according to a third embodiment; and

FIG. 14 is a schematic sectional view showing a light emitting unit, a light collecting unit and their vicinities in an exposure apparatus according to a fourth embodiment.

### DETAILED DESCRIPTION

Descriptions of the preferred embodiments will be made below separately or in different sections as necessary, but such descriptions are not irrelevant to each other unless otherwise specified. One description may be, in whole or in part, a variation or a detailed or supplementary form of another. Also, in the preferred embodiments described below, even when a numerical datum for an element (the number of pieces, numerical value, quantity, range, etc.) is indicated by a specific numerical value, it is not limited to the specific numerical value unless otherwise specified or theoretically limited to that numerical value; it may be larger or smaller than the specific numerical value.

In the preferred embodiments described below, constituent elements (including constituent steps) are not necessarily essential unless otherwise specified or theoretically essential. Similarly, in the preferred embodiments described below, when a specific form or positional relation is indicated for an element, it should be interpreted to include a form or positional relation which is virtually equivalent or similar to the specific form or positional relation unless otherwise specified or unless it should be theoretically limited to the specific form or positional relation. The same can be said of numerical data (the number of pieces, numerical value, quantity, range, etc.) as mentioned above.

Next, the preferred embodiments will be described in detail referring to the accompanying drawings. In all the drawings that illustrate the preferred embodiments, elements with like functions are designated by like reference numerals and repeated descriptions thereof are omitted. Also in the description of the preferred embodiments below, basically the same or similar explanations are not repeated except when necessary.

As for the drawings used in the description of the preferred embodiments, even in a sectional view, hatching may be omitted for easy understanding and even in a plan view, hatching may be added for easy understanding.

### First Embodiment

Next, the structure of an exposure apparatus used in the semiconductor device manufacturing method according to the first embodiment and an exposure method using the exposure apparatus will be described referring to the drawings.

### Structure of the Exposure Apparatus

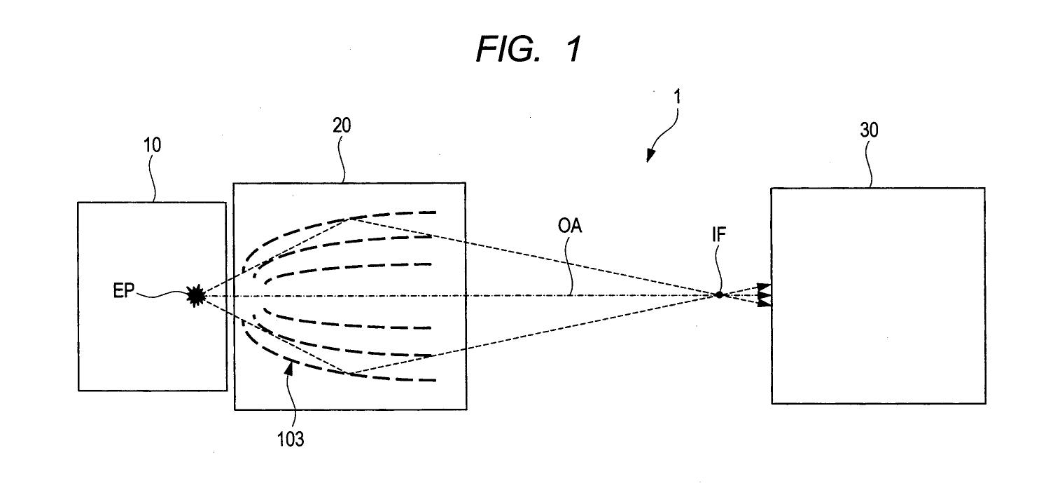

FIG. 1 is a block diagram showing the structure of the exposure apparatus used in the semiconductor device manufacturing method according to the first embodiment.

The exposure apparatus shown in FIG. 1 includes a light emitting unit 10, a light collecting unit 20, and an exposure unit 30.

In the light emitting unit 10, EUV light is generated from Xe (xenon) plasma gas. In the figure, EP represents the EUV light emitting point (plasma) in the light emitting unit 10. Sn (tin) plasma gas may be used instead of Xe plasma gas.

The light collecting unit 20 collects the EUV light generated by the light emitting unit 10 on a focal point IF (intermediate focus). The line coupling the emitting point EP and focal point IF is referred to as an optical axis (OA). The “optical axis” here means a beam of light as the center of a luminous flux passing through the entire optical system or the path through which the beam of light as the center of the luminous flux passes.

The light collected on the focal point IF is led into the exposure unit 30 and projected on the photosensitive film over the semiconductor substrate through a reticle (photo-mask, mask original).

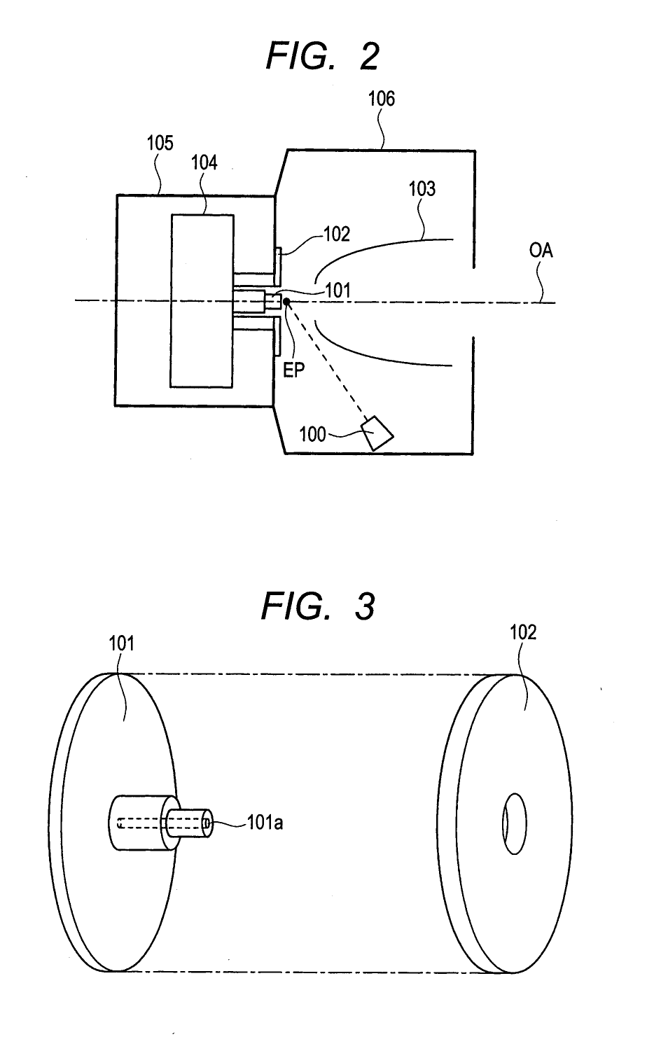

FIG. 2 is a schematic sectional view showing the structures of the light emitting unit, light collecting unit and their vicinities, though the light emitting unit 10 and light collecting unit 20 are not limited to these structures. FIG. 3 shows the negative electrode and positive electrode of the light emitting unit shown in FIG. 2 in which the negative electrode is shown on the left in a perspective view and the positive electrode is shown on the right in a perspective view.

As shown in FIGS. 2 and 3, the light emitting unit 10 includes a negative electrode (minus terminal, anode or first electrode) 101 and a positive electrode (plus terminal, cathode or second electrode) 102. The negative electrode 101 is disposed in a cylindrical form so as to surround a gas feed hole 101a in the center and the positive electrode 102 is a ring-shaped flat plate with an opening opposite to the gas feed hole 101a. The positive electrode 102 and negative electrode 101 are coupled to a high voltage power supply 104 and by applying a high electric filed between the positive electrode 102 and negative electrode 101, the material gas (Xe in this case) is turned into plasma in the area where the positive electrode 102 and negative electrode 101 face each other and for example, 13.5 nm EUV light is generated by plasma conductivity. This structure (light emitting unit 10) is covered by a case 105. In addition, the emitting point EP is arranged so that it is located in a vacuum chamber 106 and the vacuum chamber 106 is coupled to a pressure reducing means such as a pump (not shown) so that its internal reduced pressure (vacuum) can be controlled.

In the exposure apparatus (FIG. 2) according to the first embodiment, a light source for heating 100 is provided as a heating means to heat the positive electrode 102, negative electrode 101 and adjacent structural members (for example, members for coupling the negative electrode 101 to the high voltage power supply 104 and bearing members for supporting the negative pole and positive pole).

In this case, a laser radiation unit is used as the light source for heating 100. In other words, the positive electrode 102, negative electrode 101 and adjacent structural members are irradiated with laser light from the laser radiation unit to increase the temperatures of these members.

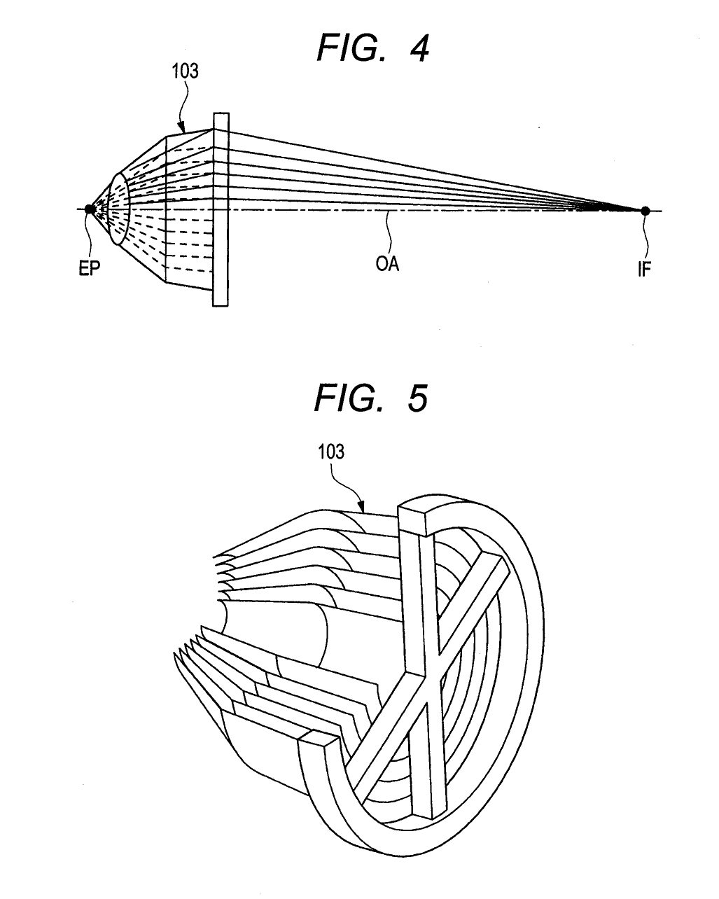

A collector 103 which configures the light collecting unit 20 is located in the vacuum chamber 106. EUV light can be collected by reflection mirrors disposed symmetrically with respect to the optical axis OA, though the structure of the light collecting unit 20 is not limited thereto. FIGS. 4 and 5 show an example of the collector (light collecting optics). Particularly, when the collector (light collecting optics) 103 includes a plurality of cylindrical reflection mirrors placed one over another at regular intervals as shown in FIGS. 4 and 5, the light collecting performance is increased. In short, the intensity of EUV light at the focal point IF can be increased.

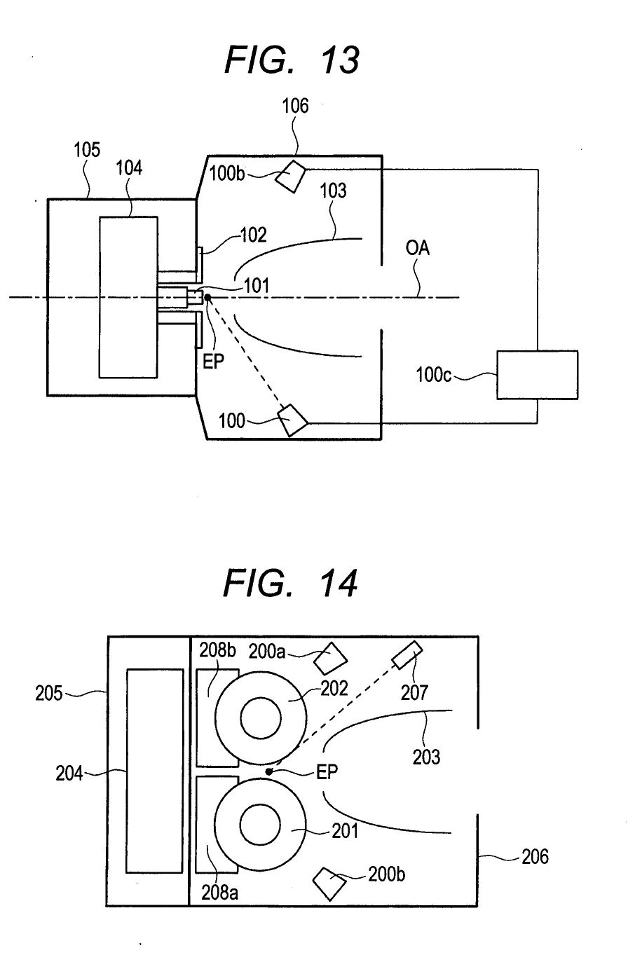

Each of the reflection mirrors shown in FIG. 4 has a conical side shape which combines a first side face with a first inclination angle and a second side face with a second inclination angle smaller than the first inclination angle. Each reflection mirror may have a virtually oval cross section. FIG. 1 schematically shows the collector 103 in which a plurality of reflection mirrors each having a virtually oval cross section are placed one over another. FIG. 2 schematically shows the outermost one among the reflection mirrors (the same is true for FIGS. 13 and 14).

Preferably the reflection mirrors are laminate mirrors which include Mo (molybdenum) and Si (silicon) layers though the reflection mirror materials are not limited thereto. When layers of materials with slightly different refraction indexes are stacked alternately in this way, EUV light can be reflected efficiently. A debris shield or DMT (debris mitigation tool) may be provided between the emitting point EP and collector 103. The DMT removes debris and enhances the light collecting performance.

In the exposure unit 30, the collected EUV light is projected on the photoresist film formed over the semiconductor substrate through the reticle so that the pattern made on the reticle is transferred to the photoresist film. The collected EUV light may be projected directly on the reticle or through the reflection mirrors on the reticle.

### Semiconductor Device Manufacturing Method

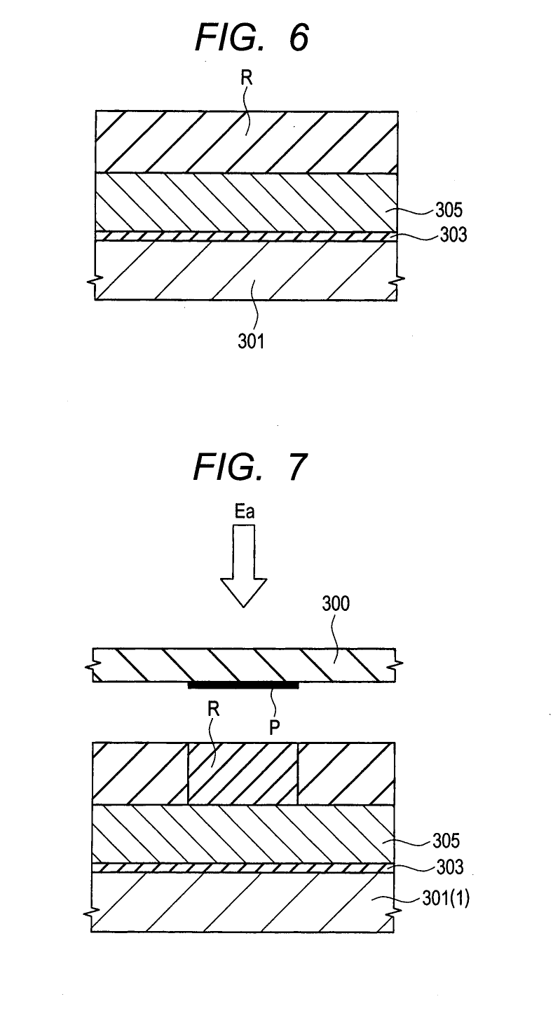

Next, the semiconductor device manufacturing method according to the first embodiment, specifically the exposure process in which EUV light is projected on the substrate through the reticle in the exposure unit to transfer the pattern on the reticle to the substrate, will be explained. FIGS. 6 to 10 are sectional views of an essential part of the substrate in the semiconductor device manufacturing process according to the first embodiment.

In the first embodiment, after (1) a heating step for the electrodes, etc. (heating step) is first carried out, (2) an exposure step is carried out as the second step. Normally at the exposure step, a plurality of semiconductor substrates 301 to be exposed are prepared and exposures are made on them one after another.

Here, as the semiconductor substrates to be exposed, a plurality of semiconductor substrates 301 are prepared, in which each substrate 301 has a conductive film 305 deposited through a gate insulating film 303 and a photoresist film (photosensitive insulating film) R formed over the entire surface of the substrate 301 as shown in FIG. 6.

At the exposure step, transfer of the mask pattern is made several times on each predetermined area of a single semiconductor substrate (namely, several exposures are made thereon or several shots are taken).

In the first embodiment, each time a series of shots for a single semiconductor substrate are completed and the substrate is replaced by another substrate, the heating step for the electrodes, etc. is carried out before starting a next series of shots.

A detailed explanation of the manufacturing process is given below.

(1) Heating Step for the Electrodes, Etc. (First Time)

First, before the first exposure step (stated later), the temperatures of the positive electrode 102, negative electrode 101 and adjacent structural members (hereinafter referred to as the “positive electrode 102 and negative electrode 101, etc.”) are increased by irradiating them with laser light from the laser radiation unit as the light source for heating 100 (This process is called the “heating step for the electrodes, etc.” See FIG. 2). For example, the temperatures of the positive electrode 102 and negative electrode 101, etc., which are the same as the room temperature (approx. 25° C.) before the heating and exposure steps, rise to 25° C. or higher. At the exposure step (stated later), the temperatures of the positive electrode 102 and negative electrode 101, etc. is increased to 1000° C. to 3000° C. by plasma radiation. Preferably the increased temperatures of the positive electrode 102 and negative electrode 101, etc. should be 1000° C. or higher and more preferably around 3000° C. In other words, the positive electrode 102 and negative electrode 101, etc. are heated preferably to 1000° C. or higher, and more preferably to around 3000° C. After heating the positive electrode 102 and negative electrode 101, etc., the laser radiation is stopped.

(2) Exposure Step (for the First Substrate)

Next, as shown in FIG. 7, a first semiconductor substrate (wafer) 301 (1) is transported to the stage (not shown) inside the exposure unit 30 (FIG. 1) and fixed on the stage. Then, an exposure is made on the first semiconductor substrate 301 (1) using the EUV light (represented by Ea in FIG. 7). The EUV light Ea is generated by the positive electrode 102 and negative electrode 101 which were heated by the heating step for the electrodes, etc. Specifically, a high electric field is applied between the heated positive electrode 102 and the heated negative electrode 101 to turn the material gas (Xe in this case) into plasma in the area where the positive electrode 102 and negative electrode 101 face each other so that the EUV light Ea is generated by plasma conductivity.

The EUV light Ea is projected through the reticle 300 on the photoresist film R to transfer the pattern made on the reticle 300 (first shot). For the first semiconductor substrate 301 (1), transfer (shot) of the pattern made on the reticle 300 to each predetermined region (for example, a region for one chip) of the substrate is repeated. When shots for all the regions are finished, the first semiconductor substrate 301 (1) is transported out of the exposure unit 30 as shown in FIG. 1.

(3) Heating Step for the Electrodes, Etc. (Second Time)

Then, the same step as the heating step for the electrodes, etc. above in (1) is carried out again. Specifically, the temperatures of the positive electrode 102 and negative electrode 101, etc. are increased by irradiating them with laser light from the laser radiation unit as the light source for heating 100. After heating the positive electrode 102 and negative electrode 101, etc., the laser radiation is stopped.

(4) Exposure Step (for the Second Substrate)

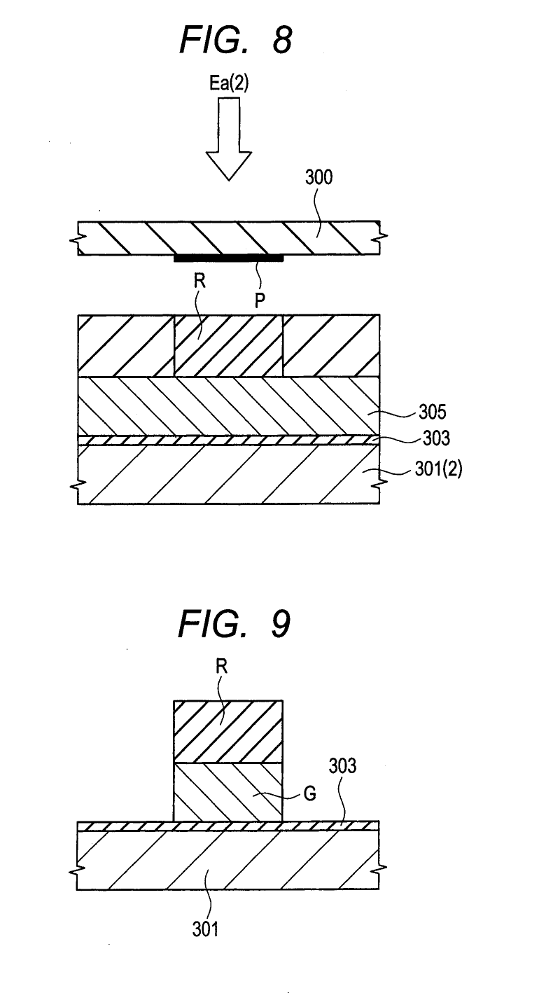

Next, as shown in FIG. 8, a second semiconductor substrate 301 (2) is transported to the stage (not shown) inside the exposure unit 30 (FIG. 1) and fixed on the stage. Then, an exposure is made on the second semiconductor substrate 301 (2) using the EUV light (represented by Ea(2) in FIG. 8). The EUV light Ea(2) is generated by the positive electrode 102 and negative electrode 101 which were heated by the heating step for the electrodes, etc. above in (3).

The EUV light Ea(2) is projected through the reticle 300 on the photoresist film R to transfer the pattern made on the reticle 300 (first shot). For the second semiconductor substrate 301 (2), transfer (shot) of the pattern on the reticle 300 to each predetermined region (for example, a region for one chip) of the substrate is repeated. When shots for all the regions are finished, the second semiconductor substrate 301 (2) is transported out of the exposure unit 30 as shown in FIG. 1.

The heating step for the electrodes, etc. and the exposure step are repeated in this way until the exposure step is finished for all the prepared semiconductor substrates. Alternatively the following sequence may be adopted: each semiconductor substrate is transported into the exposure unit 30 and preparations for exposures are made before the heating step for the electrodes, etc.

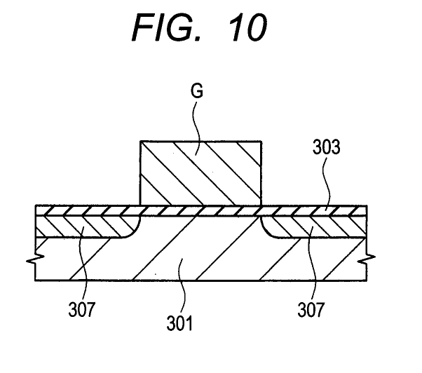

After that, as shown in FIG. 9, the photoresist film except its portion hardened by the exposure is removed using a given liquid developer and the underlying conductive film is etched using the remaining photoresist film as a mask to form, for example, a gate electrode G. Then, as shown in FIG. 10, source/drain regions 307 are formed by implanting impurity ions into the semiconductor substrate portions on both sides of the gate electrode G.

The manufacturing steps for a so-called MISFET (Metal Insulator Semiconductor Field Effect Transistor) have been described above as an example. It is needless to say that the EUV light Ea may also be used in the photolithographic steps for various components of a semiconductor device.

As mentioned above, the EUV light Ea is generated by the heated positive electrode 102 and the heated negative electrode 101, so its output (intensity) is stable and high-output exposure can be made even for the first shot. The use of this stable EUV light Ea increases the resolution and allows micro-fabrication as desired. For example, it is possible to make the gate length small enough to allow the MISFET to operate at low voltage or increase its operating speed. Furthermore, the degree of integration of the MISFET can be increased, so the device characteristics can be improved. In addition, since high-output exposure can be made even for the first shot, the problem of poor resolution can be mitigated. Also, the time required for the output of the EUV light to stabilize is shortened, leading to improvement of the throughput in the manufacture of semiconductor devices.

### Description of the Effect

The present inventors have found that when the heating step for the electrodes, etc. was not carried out before the exposure step, there was a drop in the output of EUV light between the process for the first semiconductor substrate and the process for the second semiconductor substrate.

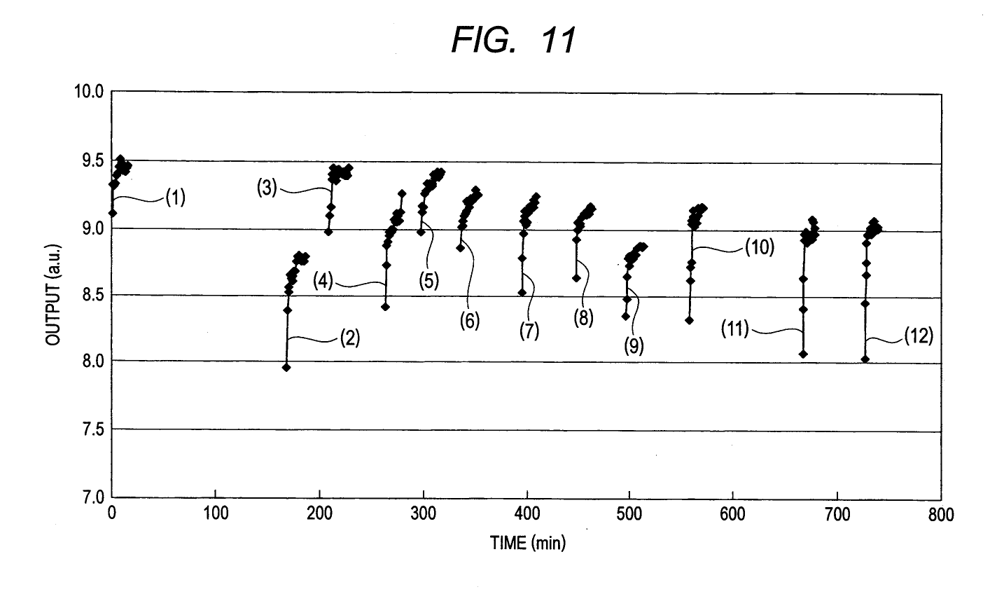

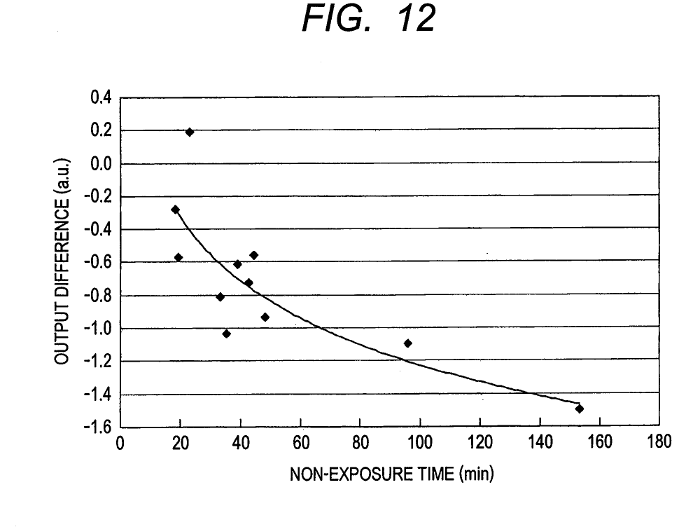

FIG. 11 is a graph showing the relation between wafer processing time (number of wafers) and output for a comparative example which does not involve a heating step for the electrodes, etc. The vertical axis represents output (a. u.) and the horizontal axis represents time (min). In the graph, (1) to (12) represent the numbers of processed wafers in which (1) indicates the output of each shot for the first wafer. Similarly, (2) to (12) indicate the output of each shot for the second to twelfth wafers. “Output” here means the intensity of EUV light impinging on the wafer surface.

As can be understood from FIG. 11, for the first (1) to twelfth (12) semiconductor substrates (wafers), the output of the first shot is low and as more shots are taken, the output becomes higher. This may be because the output of EUV light is stabilized by the plasma radiation heat generated during shots (exposures). More specifically, if emission of EUV light begins while the temperatures of the positive electrode 102 and negative electrode 101, etc. are low, the input electric energy (voltage applied to the electrodes) is partially converted into thermal energy of the electrodes, etc. and the energy applied to the plasma becomes smaller. As a consequence, the output of EUV light is considered to become lower.

Particularly, when the wafer-to-wafer interval, or non-exposure time, is long like the interval between the process for the first wafer (1) and that for the second wafer (2), there is a significant drop in the output of the first shot for the second wafer. The reason may be that the temperatures of the positive electrode 102 and negative electrode 101, etc. have decreased because of the long non-exposure time.

FIG. 12 is a graph showing the relation between non-exposure time (min) and output difference (a. u.). “Output difference” (a. u.) here means the difference obtained by subtracting the output of the last shot for the n-th wafer from the output of the first shot for the (n+1)th wafer. As can be understood from FIG. 12, the longer the non-exposure time is, the larger the output difference is. The graph of FIG. 12 approximates to the temperature cooling curve.

On the other hand, in the first embodiment, since the heating step for the electrodes, etc. is carried out before the exposure step, the output of EUV light in the first shot for the first semiconductor substrate (wafer) is higher than in the above comparative example (FIGS. 11 and 12).

In addition, since the heating step for the electrodes, etc. is carried out each time the semiconductor substrate (wafer) to be exposed is replaced, when processing a plurality of semiconductor substrates (wafers) successively, exposure with high-output EUV light is made even in the first shot for each semiconductor substrate (wafer).

In order to reduce the possibility of a drop in the output of the first shot, one possible approach may be to apply a high electric field between the heated positive electrode 102 and heated negative electrode 101 to generate plasma during a non-exposure period, for example, the time interval between the process for the first wafer (1) and that for the second wafer (2), thereby preventing the temperatures of the positive electrode 102 and negative electrode 101 from going down. However, doing so could accelerate deterioration of the positive electrode 102 and negative electrode 101 and also exert a harmful influence such as debris due to unwanted plasma radiation. By contrast, according to this embodiment, such a harmful influence is avoided and the service life of the positive electrode 102 and negative electrode 101 is lengthened. In addition, reduction of debris may lengthen the service life of the internal structural members of the exposure apparatus (for example, the collector and DMT).

Although the heating step for the electrodes, etc. is carried out after processing each semiconductor substrate (wafer) in the first embodiment, when to carry out the heating step for the electrodes, etc. is not limited thereto, but instead the heating step may be carried out after processing every two or more substrates, or periodically at regular time intervals. Alternatively the heating step may be carried out when the non-exposure time exceeds a given time period.

Although the positive electrode 102, negative electrode 101 and adjacent structural members are heated by laser radiation in the first embodiment, instead the positive electrode 102 and negative electrode 101 may be indirectly heated through heat conduction by irradiating the structural members with laser light. Any method that heats the positive electrode 102 and negative electrode 101 may be adopted.

The heating method is not limited to laser radiation as mentioned above. Several variations of the heating means will be shown in the second embodiment described next.

### Second Embodiment

Although laser radiation is adopted as a means for heating the positive electrode 102 and negative electrode 101, etc. in the first embodiment, the means is not limited thereto and any other means may be used.

### Variation 1

A halogen lamp unit may be used as the means for heating the positive electrode 102 and negative electrode 101, etc.

The positive electrode 102, negative electrode 101 and adjacent structural members are irradiated with light from the halogen lamp unit to increase the temperatures of these members. After the temperatures rise, the lamp unit is turned off.

A relatively wide area can be heated at a time by using the lamp light in this way.

### Variation 2

An induction heating unit may be used as the means for heating the positive electrode 102 and negative electrode 101, etc.

Induction heating is based on the principle of electromagnetic induction. Specifically, when an alternating current is applied to a conductive wire, lines of magnetic force which vary in direction and intensity are generated around it. When a conductive material (for example, metal) is placed near it, eddy currents flow in the conductive material under the influence of the lines of magnetic force which vary. As eddy currents flow in the conductive material, Joule heat (electric power=current squared×resistance) is generated due to its electric resistance, resulting in an increase in the temperature of the conductive material.

For example, the positive electrode 102 can be heated by placing a conductor coil near the positive electrode 102 and applying an alternating current to the coil. Also the negative electrode 101 can be heated by placing a conductor coil near the negative electrode 101 and applying an alternating current to the coil. After heating, the current to the conductor coils is stopped.

Alternatively the positive electrode 102 and negative electrode 101 may be heated indirectly by heat conduction by increasing the temperatures of the structural members adjacent to the positive electrode 102 and negative electrode 101 (for example, members for coupling the negative electrode 101 to the high voltage power supply 104 and bearing members (not shown) for supporting the negative electrode and positive electrode) by induction heating.

### Variation 3

A resistance heating unit may be used as the means for heating the positive electrode 102 and negative electrode 101, etc. For example, a conductive member is placed near the positive electrode 102 and electricity is turned on to generate Joule heat to increase the temperature of the member. The positive electrode 102 is heated indirectly with the rise in the temperature of the conductive member. Also, for example, a conductive member is placed near the negative electrode 101 and electricity is turned onto generate Joule heat to increase the temperature of the member. The negative electrode 101 is heated indirectly with the rise in the temperature of the conductive member.

Alternatively, the positive electrode 102 and negative electrode 101 may be heated indirectly by heat conduction by turning on electricity to the structural members adjacent to the positive electrode 102 and negative electrode 101 (for example, members for coupling the negative electrode 101 to the high voltage power supply 104 and bearing members (not shown) for supporting the negative pole and positive pole) to increase their temperatures.

As mentioned above, in addition to the laser radiation unit used in the first embodiment, a halogen lamp unit, induction heating unit or resistance heating unit may be used as the heating means. Particularly the use of a heating unit which can heat the positive electrode 102 and negative electrode 101 in a non-contact manner eliminates the possibility of posing a problem with the generation of EUV light (radiation) and also makes adjustments of the EUV light (for example, adjustments of the emitting point, optical axis and focal point) easy.

### Third Embodiment

In the first embodiment, the heating step for the electrodes, etc. is carried out (1) each time a predetermined number of semiconductor substrates (wafers) have been processed, (2) at regular time intervals, or (3) each time the non-exposure time exceeds a predetermined time period. Another possible approach is that the temperatures of the positive electrode 102 and negative electrode 101 are monitored and when the temperatures of the positive electrode 102 and negative electrode 101, etc. go down to below a predetermined temperature, the heating step for the electrodes, etc. is carried out.

### Structure of the Exposure Apparatus

In the third embodiment, the exposure apparatus includes a light emitting unit 10, a light collecting unit 20, and an exposure unit 30 as in the first embodiment (FIG. 1). The components other than the temperature sensor (temperature monitor, temperature detector, temperature measuring instrument, or temperature measuring unit) and the temperature controller which will be stated later are the same as in the first embodiment and their detailed description is omitted.

FIG. 13 is a schematic sectional view showing the light emitting unit, light collecting unit and their vicinities in the exposure apparatus according to the third embodiment. As shown in FIG. 13, in the exposure apparatus according to the third embodiment, a light source for heating 100 is provided as a heating means to heat the positive electrode 102, negative electrode 101, and adjacent structural members (for example, members for coupling the negative electrode 101 to the high voltage power supply 104 and bearing members (not shown) for supporting the negative pole and positive pole) as in the first embodiment.

As in the first embodiment, a laser radiation unit may be used as the light source for heating 100. In other words, as shown in FIG. 13, the positive electrode 102, negative electrode 101 and adjacent structural members are irradiated with laser light from the laser radiation unit as the light source for heating 100 to increase the temperatures of these members. A collector 103 which configures the light collecting unit 20 is located inside the vacuum chamber 106 as in the first embodiment. For the collector, a plurality of cylindrical reflection mirrors which are placed one over another at regular intervals (see FIGS. 4 and 5) may be used as in the first embodiment.

The third embodiment has a temperature sensor 100b to measure the temperatures of the positive electrode 102, negative electrode 101 and adjacent structural members.

Measurement data (measurement signal) is sent to a temperature controller 100c which controls operation of the light source for heating 100 (turning on and off the light source, radiation time, and light intensity (illuminance), etc.). For example, a radiation thermometer may be used as the temperature sensor 100b. The radiation thermometer measures the temperature of an object by measuring the intensity of infrared rays or visible light rays emitted from the object. Thermal radiation such as infrared radiation or visible light ray radiation is derived from a black-body radiation, so the temperature of the object can be calculated in accordance with the Stefan-Boltzman law which expresses the relation between temperature and radiated energy and Planck's law. By using a radiation thermometer, the temperature of the object can be measured at high speed without contact with the object.

In the third embodiment, an exposure unit 30 is provided (see FIG. 1) as in the first embodiment and inside the exposure unit, collected EUV light is projected on the photoresist film formed over the semiconductor substrate through a reticle so that the pattern on the reticle is transferred to the photoresist film.

### Semiconductor Device Manufacturing Method

Next, the semiconductor device manufacturing method according to the third embodiment, specifically the exposure process in which EUV light is projected on the substrate through the reticle in the exposure unit to transfer the pattern on the reticle to the substrate, will be explained.

In the third embodiment as well, a plurality of semiconductor substrates to be exposed are prepared and exposures are made on them one after another as in the first embodiment. Here, as the semiconductor substrates to be exposed, a plurality of semiconductor substrates 301 are prepared, in which each substrate 301 has a conductive film 305 deposited through a gate insulating film 303 and a photoresist film (photosensitive film) R formed over the entire surface of the substrate 301 (see FIG. 6) as in the first embodiment.

At the exposure step, transfer of the mask pattern is made several times on each predetermined area of a single semiconductor substrate (several exposures are made thereon or several shots are taken).

(1) Temperature Measurement and Heating Step for the Electrodes, Etc. (First Time)

First, before the first exposure step (stated later), the temperatures of the positive electrode 102, negative electrode 101 and adjacent structural members (hereinafter referred to as the “positive electrode 102 and negative electrode 101, etc.”) are measured by the temperature sensor 100b. The temperatures of the positive electrode 102 and negative electrode 101, etc. are, for example, the same as the room temperature (approx. 25° C.) and the temperatures are not higher than a predetermined temperature (threshold). Under the control of the temperature controller 100c, the temperatures of the positive electrode 102 and negative electrode 101, etc. are increased by laser radiation (see FIG. 13). Preferably the temperatures of the positive electrode 102 and negative electrode 101, etc. should rise to 1000° C. or higher and more preferably around 3000° C. Therefore, the threshold is, for example, 3000° C.

The positive electrode 102 and negative electrode 101, etc. are irradiated with laser light until their temperatures reach the threshold or higher and when they reach the threshold or higher, the laser radiation is stopped.

(2) Exposure Step (for the First Substrate)

Next, as shown in FIG. 7 in the first embodiment, a first semiconductor substrate (wafer) 301 (1) is transported to the stage (not shown) inside the exposure unit 30 (FIG. 1) and fixed on the stage. Then, an exposure is made on the first semiconductor substrate 301 (1) using the EUV light (represented by Ea in FIG. 7). The EUV light Ea is generated by the positive electrode 102 and negative electrode 101 which were heated by the heating step for the electrodes, etc. Specifically, a high electric field is applied between the heated positive electrode 102 and the heated negative electrode 101 to turn the material gas (Xe in this case) into plasma in the area where the positive electrode 102 and negative electrode 101 face each other so that the EUV light Ea is generated by plasma conductivity.

The EUV light Ea is projected through the reticle 300 on the photoresist film R to transfer the pattern made on the reticle 300 (first shot). For the first semiconductor substrate 301 (1), transfer (shot) of the pattern made on the reticle 300 to each predetermined region (for example, a region for one chip) of the substrate is repeated. When shots for all the regions are finished, the first semiconductor substrate 301 (1) is transported out of the exposure unit 30.

(3) Temperature Measurement Step (Second Time)

Then, the same step as the temperature measurement step above in (1) is carried out again. Specifically, the temperatures of the positive electrode 102 and negative electrode 101, etc. are measured by the temperature sensor 100b. If the temperatures of the positive electrode 102 and negative electrode 101, etc. are higher than the threshold, the exposure step described below in (4) (for the second substrate) is carried out. If the temperatures of the positive electrode 102 and negative electrode 101, etc. are below the threshold, the heating step for the electrodes, etc. is carried out until the temperatures reach the threshold. Specifically the positive electrode 102 and negative electrode 101, etc. are irradiated with laser light and when the temperatures reach the threshold, the laser radiation is stopped.

(4) Exposure Step (for the Second Substrate)

Next, a second semiconductor substrate 301 (2) is transported to the stage (not shown) inside the exposure unit 30 (FIG. 1) and fixed on the stage. Then, an exposure is made on the second semiconductor substrate 301 (2) using the EUV light (represented by Ea(2) in FIG. 8). The EUV light Ea(2) is generated by the positive electrode 102 and negative electrode 101 which were heated to the threshold or a higher temperature. The EUV light Ea(2) is projected through the reticle 300 on the photoresist film R to transfer the pattern made on the reticle 300 (first shot). For the second semiconductor substrate 301 (2), transfer of the pattern on the reticle 300 (shot) to each predetermined region (for example, a region for one chip) of the substrate is repeated. When shots for all the regions are finished, the second semiconductor substrate 301 (2) is transported out of the exposure unit 30 shown in FIG. 1.

After that, for each of the third and subsequent semiconductor substrates to be exposed, the temperatures of the positive electrode 102 and negative electrode 101, etc. are measured by the temperature sensor 100b before the exposure step and if the temperatures of the positive electrode 102 and negative electrode 101, etc. are below the threshold, the heating step for the electrodes, etc. is carried out until the temperatures reach the threshold.

After that, as in the first embodiment, the photoresist film except its portion hardened by the exposure is removed using a given liquid developer and the underlying conductive film is etched using the remaining photoresist film as a mask, to form, for example, a gate electrode G. Then, source/drain regions 307 are formed by implanting impurity ions into the semiconductor substrate portions on both sides of the gate electrode G (see FIGS. 9 and 10).

The manufacturing steps for a so-called MISFET (Metal Insulator Semiconductor Field Effect Transistor) have been described above as an example. It is needless to say that the EUV light Ea may also be used in the photolithographic steps for various components of a semiconductor device.

As mentioned above, in the third embodiment as well, since the EUV light Ea generated by the heated positive electrode 102 and the heated negative electrode 101 is used, high-output exposure can be made even for the first shot. The use of this stable EUV light Ea increases the resolution and allows micro-fabrication as desired. For example, it is possible to make the gate length small enough to allow the MISFET to operate at low voltage or increase its operating speed. Furthermore, the degree of integration of the MISFET can be increased, so the device characteristics can be improved. In addition, since high-output exposure can be made even for the first shot, the problem of poor resolution can be mitigated. Also, the time required for the output of the EUV light to stabilize is shortened, leading to improvement of the throughput in the manufacture of semiconductor devices.

In the third embodiment, the temperatures of the positive electrode 102 and negative electrode 101, etc. are measured by the temperature sensor 100b and the measured temperature data is fed back so that the light source for heating (laser light heating unit) 100 is driven under the control of the temperature controller 100c to carryout the exposure step more efficiently.

By specifying a threshold which does not cause the metal materials used for the positive electrode 102 and negative electrode 101 to melt, the metal materials are prevented from melting. For example, a high-melting metal such as tungsten (W) or molybdenum (Mo) is used as the material for the negative electrode 101. W has a melting point of 3422° C. and Mo has a melting point of 2623° C. According to the third embodiment, the electrodes, etc. can be heated within a temperature range similar to the temperature range for plasma generation as far as possible, by temperature control depending on the electrode material, namely to an extent that the melting point of the electrode material is not exceeded.

### Fourth Embodiment

Although a “hollow cathode type” electrode is used for the light emitting unit in the first to third embodiments, the type of electrodes of the light emitting unit is not limited and, for example, a “rotary” electrode as described below may be used for the light emitting unit.

The components other than the light emitting unit are the same as in the first embodiment and the structure of the light emitting unit is described below.

FIG. 14 is a schematic sectional view showing the light emitting unit, light collecting unit and their vicinities in an exposure apparatus according to the fourth embodiment. As shown in FIG. 14, the light emitting unit includes a rotary negative electrode (minus terminal, anode or first electrode) 202 and a rotary positive electrode (plus terminal, cathode or second electrode) 201. The negative electrode 202 is located in a way that it can be in contact with a molten plasma material (for example, molten tin) in a plasma material bath 208b. Therefore, as the negative electrode 202 rotates, molten tin adheres to the cylindrical electrode surface and the molten tin is conveyed to the vicinity of the plasma generating point (light emitting point EP). Similarly, the positive electrode 201 is located in a way that it can be in contact with a molten plasma material (for example, molten tin) in a plasma material bath 208a. Therefore, as the positive electrode 201 rotates, molten tin adheres to the cylindrical electrode surface and the molten tin is conveyed to the vicinity of the plasma generating point (emitting point EP).

The positive electrode 201 and negative electrode 202 are coupled to a high voltage power supply 204 and a high electric field is applied between them to turn the molten tin into plasma in the area where the positive electrode 201 and negative electrode 202 face each other, in this case at the point where the molten tin on the negative electrode 202 and the molten tin on the positive electrode 201 are the closest to each other (emitting point EP), so that EUV light is generated by plasma conductivity.

In this light emitting unit, laser light from a laser light source 207 accelerates (assists) the process of turning molten tin into plasma.

The light emitting unit is partially covered by a case 205 as in the first embodiment. The emitting point EP is arranged in a way to be located in a vacuum chamber 206 and the vacuum chamber 206 is coupled to a pressure reducing means such as a pump (not shown) so that its internal reduced pressure (vacuum) can be controlled.

In the exposure apparatus according to the fourth embodiment (FIG. 14), heating light sources 200a and 200b are provided as heating unit to heat the positive electrode 201, negative electrode 202, and adjacent structural members (for example, members for coupling the negative electrode and positive electrode to the high voltage power supply and bearing members (not shown) for supporting the negative pole and positive pole). Laser radiation units are used as the heating light sources 200a and 200b. For example, the heating light source 200a is used to heat the negative electrode 202 and adjacent structural members and the heating light source 200b is used to heat the positive electrode 201 and adjacent structural members. Specifically, as shown in FIG. 14, the negative electrode 202 and adjacent structural members are irradiated with laser light from the laser radiation unit as the heating light source 200a to increase the temperatures of these members. Also, as shown in FIG. 14, the positive electrode 201 and adjacent structural members are irradiated with laser light from the laser radiation unit as the heating light source 200b to increase the temperatures of these members.

A collector 203 which configures the light collecting unit 20 is located inside the vacuum chamber 206 as in the first embodiment. For the collector (light collecting optics) 103, a plurality of cylindrical reflection mirrors which are placed one over another at regular intervals (see FIGS. 4 and 5) may be used as in the first embodiment.

In the fourth embodiment as well, an exposure unit 30 is provided (see FIG. 1) as in the first embodiment and in the exposure unit, collected EUV light is projected on the photoresist film formed over the semiconductor substrate through a reticle so that the pattern on the reticle is transferred to the photoresist film.

As mentioned above, the heating step for the electrodes, etc. is carried out for each semiconductor substrate (wafer) using the heating light sources 200a and 200b as in the first embodiment, so the fourth embodiment brings about the same effect as in the first embodiment.

When to carry out the heating step for the electrodes, etc. is not limited, but instead of carrying out the heating step after processing each semiconductor substrate (wafer), the heating step may be carried out after processing every two or more substrates, or periodically at regular time intervals. Alternatively the heating step may be carried out when the non-exposure time exceeds a given time period.

Although the positive electrode 201, negative electrode 202 and adjacent structural members are heated by laser radiation in the fourth embodiment, instead the positive electrode 201 and negative electrode 202 may be indirectly heated by heat conduction by irradiating the structural members with laser light. Any method that heats the positive electrode 201 and negative electrode 202 may be adopted.

The heating method is not limited to laser radiation as mentioned above. Any of the variations of the heating means as suggested by the second embodiment may be used.

Furthermore, as in the third embodiment, a temperature sensor may be provided to measure the temperatures of the positive electrode 201, negative electrode 202 and adjacent structural members. Measurement data (measurement signal) is sent to the temperature controller 100c which controls operation of the heating light sources 202a and 202b (turning on and off the light sources, radiation time, and light intensity (illuminance), etc.) (see FIG. 13). For example, a radiation thermometer may be used as the temperature sensor 100b.

The same effect as in the third embodiment can be achieved when the following procedure is taken: the temperatures of the positive electrode 201 and negative electrode 202, etc. are measured by the temperature sensor 100b before carrying out the exposure step for each semiconductor substrate and if the temperatures are below a threshold, the heating step for the electrodes, etc. is carried out until the temperatures reach the threshold.

The invention made by the present inventors has been so far explained concretely in reference to the preferred embodiments thereof. However, the invention is not limited thereto and it is obvious that these details may be modified in various ways without departing from the spirit and scope thereof.

The present invention can be effectively applied to semiconductor device manufacturing methods, exposure methods, exposure apparatuses and light sources for exposure apparatuses.

What is claimed is:

1. A semiconductor device manufacturing method comprising the steps of:
(a) making preparations for use of an exposure apparatus, the apparatus comprising:
(a1) a light emitting unit with a first electrode and a second electrode for generating EUV light;
(a2) a heating unit for heating the first electrode and the second electrode; and
(a3) an exposure unit for projecting the EUV light on a substrate through a mask;
(b) heating the first electrode and the second electrode by the heating unit;
(c) after the step (b) above, applying a voltage between the first electrode and the second electrode and generating EUV light by plasma excitation of predetermined atoms; and
(d) leading the EUV light into the exposure unit and making an exposure on a photosensitive film formed over the substrate inside the exposure unit.

2. The semiconductor device manufacturing method according to claim 1, wherein the predetermined atoms are Xenon or Sn (tin).

3. The semiconductor device manufacturing method according to claim 1,
wherein the heating unit is a laser radiation unit, and
wherein at the step (b), the first electrode and the second electrode are heated by irradiating the first electrode and the second electrode with laser light from the laser radiation unit.

4. The semiconductor device manufacturing method according to claim 1,
wherein the heating unit is a halogen lamp unit, and
wherein at the step (b), the first electrode and the second electrode are heated by irradiating the first electrode and the second electrode with light from the halogen lamp unit.

5. The semiconductor device manufacturing method according to claim 1,
wherein the heating unit is an induction heating unit, and
wherein at the step (b), the first electrode and the second electrode are heated by induction heating.

6. The semiconductor device manufacturing method according to claim 1,
wherein the heating unit is a resistance heating unit, and
wherein at the step (b), the first electrode and the second electrode are heated by resistance heating.

7. The semiconductor device manufacturing method according to claim 1, the exposure apparatus further including:
(a4) a temperature measuring unit for the first electrode and the second electrode.

8. The semiconductor device manufacturing method according to claim 1, the exposure apparatus further including:
(a4) a temperature measuring unit for the first electrode and the second electrode; and
(a5) a temperature controller for controlling the heating unit according to temperatures of the first electrode and the second electrode,
wherein the step (b) is carried out when the temperatures of the first electrode and the second electrode are below a predetermined temperature.

9. The semiconductor device manufacturing method according to claim 7, wherein the temperature measuring unit includes a radiation thermometer.

10. The semiconductor device manufacturing method according to claim 1,
wherein at the step (d) a specified number of substrates are exposed sequentially, and
wherein the step (d) includes another heating step for heating the first electrode and the second electrode by the heating unit between:
(d1) a n-th exposure step for an n-th substrate among the specified number of substrates; and
(d2) a (n+1)th exposure step for an (n+1)th substrate.

11. The semiconductor device manufacturing method according to claim 10, the exposure apparatus further including:
(a4) a temperature measuring unit for the first electrode and the second electrode;
(a5) a temperature controller for controlling the heating unit according to temperatures of the first electrode and the second electrode,
wherein the temperatures of the first electrode and the second electrode after the step (d1) are below a predetermined temperature, and
wherein at the other heating step the first electrode and the second electrode are heated to the predetermined temperature or higher.

12. The semiconductor device manufacturing method according to claim 10,
wherein the step (d1) includes a plurality of exposure steps for each demarcated predetermined region of the n-th substrate,
wherein the other heating step includes a plurality of exposure steps for each demarcated predetermined region of the (n+1)th substrate.

13. An exposure apparatus comprising:
(a1) a light emitting unit with a first electrode and a second electrode which generates EUV light by plasma excitation of predetermined atoms between the first electrode and the second electrode by applying a voltage between the first electrode and the second electrode;
(a2) a heating unit for heating the first electrode and the second electrode; and
(a3) an exposure unit for projecting the EUV light on a substrate through a mask.

14. The exposure apparatus according to claim 13, further comprising:
(a4) a temperature measuring unit for the first electrode and the second electrode; and
(a5) a temperature controller for controlling the heating unit according to temperatures of the first electrode and the second electrode.

15. The exposure apparatus according to claim 13, wherein the heating unit is a laser radiation unit, halogen lamp unit, induction heating unit or resistance heating unit.

16. An exposure method for an exposure apparatus which uses the exposure apparatus, the apparatus comprising:
(a1) a light emitting unit with a first electrode and a second electrode for generating EUV light by plasma excitation of predetermined atoms between the first electrode and the second electrode by applying a voltage between the first electrode and the second electrode;
(a2) a heating unit for heating the first electrode and the second electrode; and
(a3) an exposure unit for projecting the EUV light on a substrate through a mask;
the method comprising the steps of:
(b) leading the EUV light into the exposure unit and making an exposure on a photosensitive film formed over the substrate inside the exposure unit; and
before the step (b), (c) heating the first electrode and the second electrode by the heating unit.

17. A light source for an exposure apparatus, comprising:
(a1) a light emitting unit with a first electrode and a second electrode for generating EUV light by plasma excitation of predetermined atoms between the first electrode and the second electrode by applying a voltage between the first electrode and the second electrode; and
(a2) a heating unit for heating the first electrode and the second electrode.
